(19) United States
(12) Patent Application Publication
(10) Pub. No.: US 2022/0074624 A1
(43) Pub. Date: Mar. 10, 2022

(54) BLOCK HEATER AND BLOCK HEATER ASSEMBLY

(71) Applicant: JUSUNG ENGINEERING CO., LTD., Gwangju-si, Gyeonggi-do (KR)

(72) Inventors: Myeong Ki MIN, Gwangju-si, Gyeonggi-do (KR); Jeong Kuk KIM, Gwangju-si, Gyeonggi-do (KR); Se Young OH, Gwangju-si, Gyeonggi-do (KR); Tae Ho LEE, Gwangju-si, Gyeonggi-do (KR)

(21) Appl. No.: 17/414,316

(22) PCT Filed: Dec. 11, 2019
(86) PCT No.: PCT/KR2019/017434

§ 371 Date: Jun. 15, 2021

(30) Foreign Application Priority Data
Dec. 17, 2018 (KR) 10-2018-0163044
Dec. 6, 2019 (KR) 10-2019-0161569

(51) Int. Cl. F24H 3/08; F24H 9/18

(52) U.S. Cl. CPC F24H 3/08; F24H 9/18

(57) ABSTRACT

A block heater is disclosed. The block heater may include a heating element configured to supply predetermined heat to a gas line and a heat transfer unit disposed between the gas line and the heating element to transfer heat to the gas line, wherein the heat transfer unit may include a convex portion or a concave portion formed on at least one side thereof in a longitudinal direction of the gas line.

### TECHNICAL FIELD

The present inventive concept relates to a block heater and a block heater assembly.

### BACKGROUND ART

In general, a chemical vapor deposition (CVP) process is a process of evaporating a liquid-phase material into an evaporated gas and depositing the evaporated gas on the surface of a semiconductor device in the form of a thin film. In the chemical vapor deposition process, if heat is not uniformly transferred to a gas line, which is a path along which the evaporated gas flows, the liquid-phase material is non-uniformly heated, whereby defects, such as particles, are generated. Therefore, the extent to which uniform temperature is provided over the entire gas line is connected directly with semiconductor manufacturing efficiency.

In order to solve the above problem, research has been steadily conducted on a block heater as a means for heating the gas line to uniform temperature.

FIG. 1 is a view schematically showing the construction of a conventional block heater.

Referring to FIG. 1, a semiconductor manufacturing apparatus 1 is configured such that a block heater 40 configured to heat a gas line 30 is disposed between an evaporator 10 and a chamber 20 and such that the block heater 40 includes a plurality of divided unit heating modules 41, 43, and 45. However, the conventional block heater has the following problems.

When carefully observing the connection structure of the block heater 40 shown in region A of FIG. 1, a predetermined gap is formed between adjacent ones of the unit heating modules 41, 43, and 45, which contact each other, due to the difference in coefficient of thermal expansion between the gas line 30 and the block heater 40, and a portion of the gas line 30 is exposed outwards through each gap.

A cold spot is formed at the exposed portion of the gas line 30 due to a decrease in thermal conductivity, and evaporated gas is liquefied again, whereby the gas line may be clogged and defective particles are generated.

Therefore, there is a need for the connection structure of the block heater that provides uniform temperature within a predetermined section of the gas line in order to secure stability of evaporated gas.

### DISCLOSURE

### Technical Problem

Embodiments provide a block heater and a block heater assembly, wherein the shape of heat transfer units is changed such that adjacent block heaters are connected to each other while overlapping each other, whereby it is possible to provide uniform temperature within a predetermined section of a gas line.

The technical objects that can be achieved through the embodiments are not limited to what has been particularly described hereinabove, and other technical objects not described herein will be more clearly understood by those skilled in the art from the following detailed description.

### Technical Solution

In one embodiment, a block heater includes a heating element configured to supply predetermined heat to a gas line and a heat transfer unit disposed between the gas line and the heating element to transfer heat to the gas line, wherein the heat transfer unit includes a convex portion or a concave portion formed on at least one side thereof in a longitudinal direction of the gas line.

The heat transfer unit may be made of an aluminum (Al) material exhibiting excellent heat conduction efficiency.

An aluminum oxide (Al₂O₃) film may be formed on the surface of the heat transfer unit by anodization.

The heating element may be a planar heating element.

The block heater may further include a cover plate disposed opposite the heat transfer unit in the state in which the heating element is disposed therebetween, wherein an air gap may be formed between the outer surface of the cover plate and the inner surface of a housing.

The heat transfer unit may include a first recess having a shape corresponding to the shape of the gas line and a second recess disposed adjacent to the first recess, the second recess having a shape corresponding to the shape of a connection member mounted to the end of the gas line.

In another embodiment, a block heater assembly includes a plurality of block heaters, each of the block heaters including a heat transfer unit, wherein convex portions or concave portions are disposed at opposite ends of the heat transfer unit, and the heat transfer units are coupled to each other through engagement between each of the convex portions and a corresponding one of the concave portions.

Each of the block heaters may include at least one heating element configured to supply predetermined heat to the gas line.

One surface of each of the convex portions may contact the surface of the gas line, and one surface of each of the concave portions may contact the other surface of a corresponding one of the convex portions while being spaced apart from the gas line.

The block heater assembly may further include a connection unit disposed between the heat transfer units, wherein the connection unit may be made of a material exhibiting the same thermal conductivity as the heat transfer units.

### Advantageous Effects

According to at least one embodiment of the present invention, heat having uniform temperature is provided within a predetermined section of a gas line, whereby a change in state of processing gas flowing in the gas line is inhibited, the amount of defective particles is remarkably reduced, and the quality of a deposited film is improved.

It should be noted that the effects of the present invention are not limited to the effects mentioned above, and other unmentioned effects will be clearly understood by those skilled in the art from the above description of the present invention.

### DESCRIPTION OF DRAWINGS

FIG. 1 is a view schematically showing the construction of a conventional block heater;

FIG. 2 is a view schematically showing the construction of a semiconductor manufacturing apparatus including a block heater assembly according to an embodiment of the present invention;

FIG. 3 is an exploded perspective view of the block heater assembly shown in FIG. 2;

FIG. 4 is a sectional view of a block heater taken along line 1-1′ of FIG. 2;

FIG. 5 is a perspective view showing a heat transfer unit of a block heater assembly according to an embodiment of the present invention;

FIG. 6 is a perspective view showing a heat transfer unit of a block heater assembly according to another embodiment of the present invention;

FIG. 7 is a perspective view showing a heat transfer unit of a block heater assembly according to another embodiment of the present invention;

FIG. 8 is a view illustrating a block heater applied to a gas line including a three-way valve according to an embodiment of the present invention; and

FIG. 9 is a perspective view showing a block heater assembly according to a further embodiment of the present invention.

### BEST MODE

Reference will now be made in detail to the preferred embodiments, examples of which are illustrated in the accompanying drawings. While embodiments are susceptible to various modifications and alternative forms, specific embodiments thereof are shown by way of example in the drawings.

It may be understood that, although the terms “first,” “second,” etc. may be used herein to describe various elements, these elements are not to be limited by these terms. In addition, relational terms, such as “on/upper part/above” and “under/lower part/below,” are used only to distinguish between one subject or element and another subject or element without necessarily requiring or involving any physical or logical relationship or sequence between such subjects or elements.

The terms used in this specification are provided only to explain specific embodiments, but are not intended to restrict the present invention. A singular representation may include a plural representation unless it represents a definitely different meaning from the context.

Hereinafter, a block heater and a block heater assembly according to embodiments will be described with reference to the accompanying drawings.

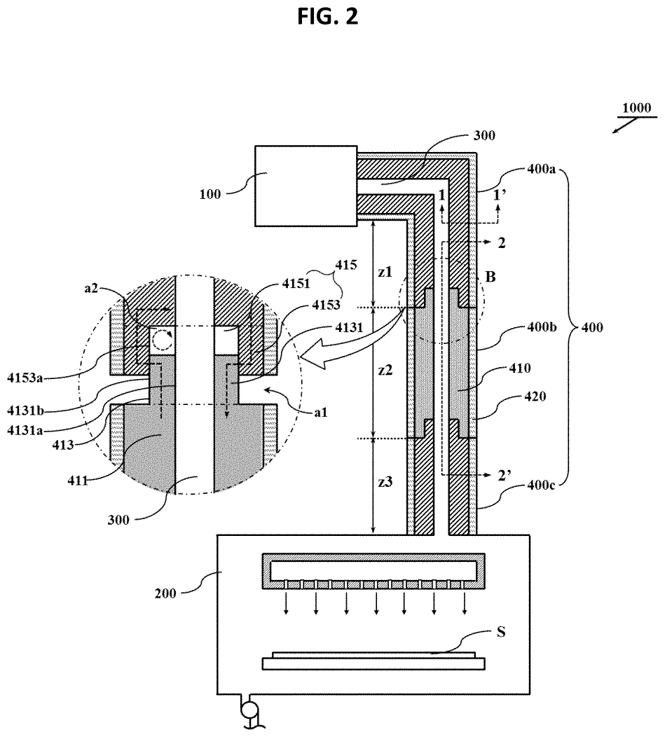

FIG. 2 is a view schematically showing the construction of a semiconductor manufacturing apparatus including a block heater assembly according to an embodiment of the present invention

Referring to FIG. 2, the semiconductor manufacturing apparatus 1000 includes an evaporator 100 configured to evaporate a liquid-phase processing material, a processing chamber 200 configured to spray processing gas supplied from the evaporator 100 thereinto in order to deposit a thin film on a substrate S, a gas line 300 disposed between the evaporator 100 and the processing chamber 200 in order to define a channel of the processing gas, and a block heater assembly 400 configured to uniformly heat the entire gas line 300.

The block heater assembly 400 may include a plurality of block heaters 400a, 400b, and 400c respectively provided in a plurality of partitioned heating zones z1, z2, and z3.

Each of the block heaters 400a, 400b, and 400c is an individual unit constituting the block heater assembly 400, and the block heater assembly 400 is an assembly in which the block heaters 400a, 400b, and 400c are coupled to each other. The block heater assembly 400 may provide heat having uniform temperature to the entire gas line 300. In FIG. 2, the block heater assembly is shown as including three block heaters, which, however, is merely illustrative. The number of block heaters may be changed depending on the length of the gas line or the design of an engineer.

Since the block heater assembly 400 includes the block heaters 400a, 400b, and 400c, which are individual units, as described above, the individual units may be easily detached from and attached to each other during maintenance.

Each of the block heaters 400a, 400b, and 400c may include a heat transfer unit 410 configured to receive the gas line 300, a housing 420 configured to enclose the heat transfer unit 410 and to define the external appearance of the block heater, and a heating element (not shown) configured to supply predetermined heat.

The heat transfer unit 410 may include a rectangular block body 411 and a convex portion 413 or a concave portion 415 formed on at least one side or the other side thereof in the longitudinal direction of the gas line 300. Here, the convex portion 413 and/or the concave portion 415 of the heat transfer unit 410 serves as a connection portion for coupling between adjacent block heaters. Meanwhile, the end of the heat transfer unit 410 formed at one side or the other side of each of the block heaters 400a and 400c, which communicate with the evaporator 100 and/or the processing chamber 200, may have a flat surface.

The convex portion 413 may include a coupling protrusion 4131 formed at the outer surface of the block body 411 so as to protrude a predetermined length.

The concave portion 415 may include a coupling recess 4151 formed at the outer surface of the block body 411 so as to be depressed a predetermined length and sidewalls 4153 provided at opposite ends thereof due to formation of the coupling recess 4151.

Now, the coupling structure between adjacent block heaters shown in FIG. 2 will be described.

The coupling protrusion 4131 of the convex portion 413 formed at one side of the second block heater 400b is inserted into and settled in the coupling recess 4151 of the concave portion 415 formed at the other side of the first block heater 400a, whereby the first block heater 400a and the second block heater 400b are coupled to each other.

The coupling recess 4151 of the concave portion 415 formed at the other side of the second block heater 400b receives the coupling protrusion 4131 of the convex portion 413 formed at one side of the third block heater 400c, whereby the second block heater 400b and the third block heater 400c are coupled to each other.

As described above, the convex portion 413 and the concave portion 415 of the heat transfer unit 410 are engaged with each other in the longitudinal direction of the gas line 300, whereby adjacent block heaters are tightly fastened to each other through fitting, and, in the coupling region B between the adjacent block heaters, the coupling protrusion 4131 of the convex portion 413 and the sidewall 4153 of the concave portion 415 overlap each other in a direction perpendicular to the longitudinal direction of the gas line 300. In addition, one surface 4131a of the convex portion 413 contacts the gas line 300, and one surface 4153a of the concave portion 415 contacts the other surface 4131b of the convex portion 413 while being spaced apart from the gas line 300.

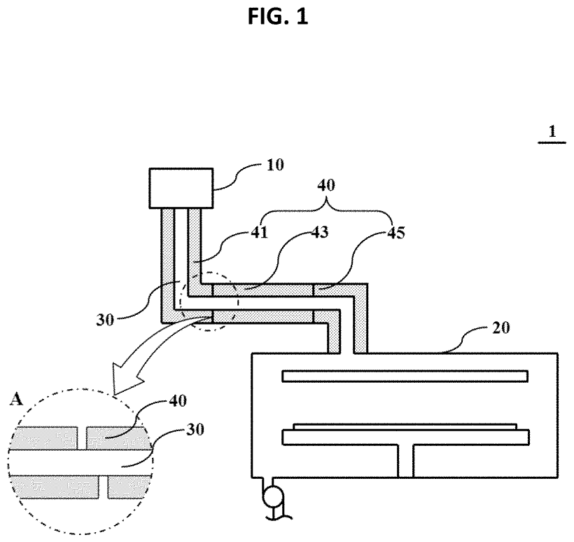

Unlike the conventional block heater 40 shown in FIG. 1, the block heater assembly 400 according to the embodiment is configured such that the convex portion 413 and the concave portion 415 of the adjacent block heaters are formed so as to have a staggered structure and are coupled to each other, whereby uniform distribution of temperature may be maintained over the entire gas line 300. Alternatively, the block heater assembly 400 may uniformly heat the gas line in the partitioned heating zones z1, z2, and z3.

Referring to the enlarged view of the coupling region B shown in FIG. 2, even though a predetermined gap al is formed between the adjacent first and second block heaters 400a and 400b due to the difference in coefficient of thermal expansion between the gas line 300 and the heat transfer unit 410, a heat conduction path is defined along arrows (straight lines) between the sidewall 4153 of the first block heater 400a and the coupling protrusion 4131 of the second block heater 400b, which overlap each other. Along the heat conduction path, heat supplied from the first block heater 400a is conducted to the second block heater 400b, and heat supplied from the second block heater 400b is conducted to the first block heater 400a, whereby it is possible to remarkably reduce temperature deviation generated at the gap region al.

In addition, a space that is hermetically sealed by the coupling recess 4151 of the first block heater 400a and the coupling protrusion 4131 of the second block heater 400b is defined in a predetermined gap g2, and a heat convection path is defined along an arrow (a concentric circle) in the hermetically sealed space. Since heat supplied from the first and second block heaters 400a and 400b is transferred to the gas line 300 along the heat convection path, it is possible to prevent a cold spot from being formed at a portion of the gas line 300.

As described above, the block heater assembly 400 according to the embodiment is configured to have a structure in which the heat transfer units 410 of the adjacent block heaters overlap each other while being staggered, whereby it is possible to reduce temperature deviation between the block heaters and at the same time to prevent a cold spot from being formed at a portion of the gas line 300. Consequently, the processing gas flowing in the gas line 300 does not change in phase (for example, from a gas phase to a liquid phase), whereby the quality of a deposited film may be improved. In addition, it is possible to easily achieve alignment during assembly, and it is also possible to prevent loss of heat to the outside through maximum contact between surfaces. Hereinafter, a process of assembling a block heater according to an embodiment will be described.

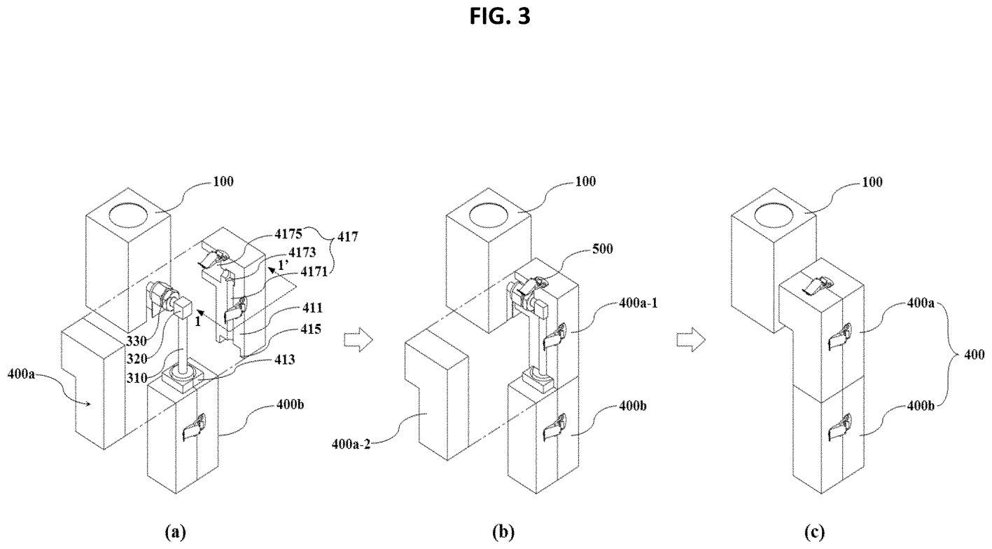

FIG. 3 is an exploded perspective view of the block heater assembly shown in FIG. 2.

Referring to FIG. 3(a), a block heater assembly 400 according to an embodiment may include a plurality of block heaters 400a and 400b, and each of the block heaters 400a and 400b may be formed in a symmetrical structure in which the block heater is separable into upper and lower parts or left and right parts.

The gas line 300 includes a circular pipe 310, a body 320 of a two-way valve, and a connection member 330 having a bolt mounted thereto.

The heat transfer unit 410 of the first block heater 400a has a shape corresponding to the shape of the gas line 300 so as to be tightly fitted onto the gas line 300. The heat transfer unit 410 includes concave recesses 4171 and 4173 formed in the portions thereof corresponding to the pipe 310 and the body 320 of the two-way valve of the gas line 300 so as to come into surface contact with the gas line 300 and a step recess 4175 formed in the portion thereof corresponding to the connection member 330 having the bolt mounted thereto of the gas line 300 so as to contact the gas line irrespective of the position of the bolt. As described above, a plurality of recesses 417 is formed in the heat transfer unit 410 such that contact area is increased over the entire gas line 300. This construction is provided to uniformly conduct predetermined heat from the heat transfer unit 410 to the gas line. If such a contact state is released at a specific portion, heat conduction efficiency at the portion may be remarkably reduced.

Referring to FIG. 3(b), a first unit block heater 400a-1 of the first block heater 400a, which is formed in a symmetrical structure, is assembled in a direction perpendicular to the longitudinal direction of the gas line 300 and is thus uniformly brought into tight contact with the gas line 300, which is an object to be heated. Here, a fastening means 500, such as a fastener or a catch clip, is provided at the upper part and/or the side part of the first unit block heater 400a-1.

Referring to FIG. 3(c), a second unit block heater 400a-2 of the first block heater 400a, which is formed in a symmetrical structure, is uniformly brought into tight contact with the gas line 300, which is an object to be heated, and at the same time is firmly fastened and coupled to the first unit block heater 400a-1 by the fastening means 500 provided at the first unit block heater 400a-1.

Meanwhile, as previously described, the first unit block heater 400a-1 and the second unit block heater 400a-2, which constitute the first block heater 400a, are symmetric with respect to the longitudinal direction of the gas line 300, and the unit block heaters 400a-1 and 400a-2 include the same components.

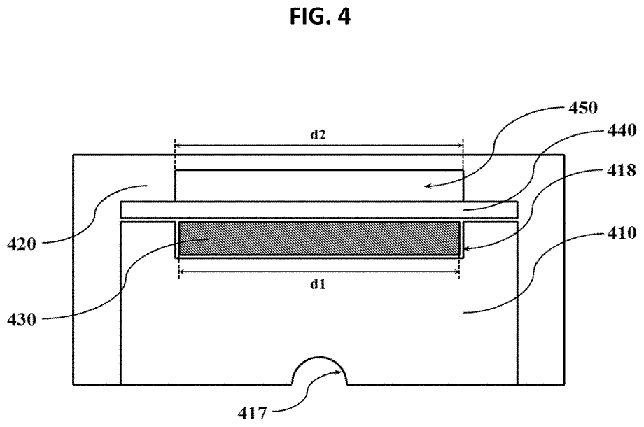

Hereinafter, the components of the block heater will be described with reference to the sectional view of the block heater shown in FIG. 4.

FIG. 4 is a sectional view of the block heater taken along line 1-1′ of FIG. 2.

Referring to FIG. 4, the block heater 400a may include a heat transfer unit 410 configured to receive the gas line 300, a housing 420 configured to enclose the heat transfer unit 410 and to define the external appearance of the block heater, a heating element 430 configured to supply predetermined heat, and a cover plate 440 configured to cover the heating element 430.

The heat transfer unit 410 may be formed so as to correspond to the shape of the gas line 300, and may contact the surface of the gas line 300 such that predetermined heat supplied from the heating element 430 is conducted to the gas line 300.

The heat transfer unit 410 may be made of a material that exhibits high thermal conductivity. For example, the heat transfer unit 410 may include any one selected from the group consisting of aluminum (Al), copper (Cu), silver (Ag), tungsten (W), and combinations thereof; however, the present invention is not limited thereto. A heat transfer unit 410 made of a material that exhibits high thermal conductivity may smoothly conduct heat supplied from the heating element 430 to the gas line 300.

The surface of the heat transfer unit 410 is anodized so as to exhibit high corrosion resistance and wear resistance. An aluminum oxide (Al₂O₃) film may be formed on the surface of the heat transfer unit 410 by anodization.

At least one recess 417 (for example, concave recesses 4171 and 4173 and a step recess 4175) having a shape corresponding to the shape of the outer circumferential surface of the gas line 300 is formed in one end of the heat transfer unit 410, and a receiving recess 419 depressed to a predetermined depth so as to receive the heating element 430 may be formed in the other end of the heat transfer unit 410.

The heating element 430 may supply predetermined heat to the heat transfer unit 410 such that processing gas flowing in the gas line 300 is heated to uniform temperature.

The heating element 430 may be a planar heating element configured such that a heating region is uniformly distributed over the entire area thereof so as to have uniform distribution of temperature.

The heating element 430 may be settled in the receiving recess 419 formed in the other end of the heat transfer unit 410. At this time, the depth or the width of the receiving recess 419 may correspond to the thickness or the width of the heating element 430 such that neither separate space nor air pocket is formed between the receiving recess 419 and the heating element 430. The reason for this is that, in the case in which an air pocket is formed at the joint surface between the receiving recess 419 and the heating element 430, uniform temperature may not be provided to the heat transfer unit 410 due to partial emission of heat.

The cover plate 440 is disposed opposite the heat transfer unit 410 in the state in which the heating element 430 is disposed therebetween. In addition, the cover plate 440 is disposed on the other end of the heat transfer unit 410 and on the heating element 430 so as to cover the heating element 430 settled in the receiving recess 419.

The cover plate 440 may be provided to improve uniformity in heat emitted from the heating element 430 and to fix the position of the heating element 430, and may be made of, for example, a silicon carbide (SiC) material.

The housing 420 may enclose the heat transfer unit 410 and/or the cover plate 440, and may define the external appearance of the block heater 400a.

The housing 420 may be made of an insulating material that exhibits high heat resistance in order to prevent heat supplied from the heating element 430 from escaping the block heater 400a. Poly ether ether ketone (PEEK) may be used as an example of the insulating material that exhibits high heat resistance.

In addition, a coating layer configured to reflect heat emitted from the heating element 430 to the heat transfer unit 410 may be provided on the inner surface of the housing 420 in order to improve heat insulation or heat emission performance.

A predetermined air gap 450 may be formed between the inner surface of the housing 420 and the outer surface of the cover plate 440. The reason for this is that, in the case in which no air gap 450 is formed in the housing 420, heat generated by the heating element 430 may be conducted into the housing 420 through the cover plate 440 and heat insulation performance of the housing 420 may be remarkably reduced due to the conducted heat.

In the block heater 400a according to the embodiment, therefore, the separate air gap 450 is formed in the housing 420, whereby it is possible to control a heat flow path between the heating element 430 and the housing 420 and to secure heat insulation performance of the housing 420.

At this time, the width d1 of the air gap 450 may be equal to or may correspond to the width d2 of the heating element 430. Alternatively, the area of the air gap 450 may be equal to or may correspond to the area of the heating element 430.

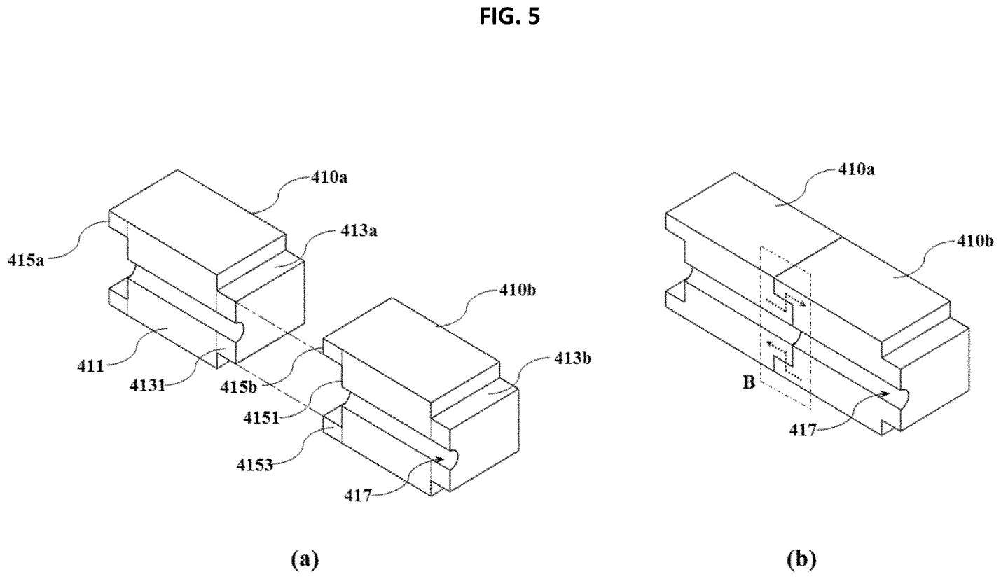

Meanwhile, as previously described, the heating element 430 is designed so as to be covered by the receiving recess 419 of the heat transfer unit 410 and the cover plate 440 in order to provide heat having uniform temperature. At this time, the heating element 430 is not directly disposed at one side and/or the other side of the heat transfer unit 410 for a reason related to design. Therefore, there is a need to improve heat conduction efficiency at one side and/or the other side of the heat transfer unit 410 that is connected to an adjacent block heater in order to prevent the occurrence of a local difference in temperature over the entire gas line 300. This will be described hereinafter with reference to FIGS. 5 to 7.

FIGS. 5 to 7 are perspective views of the heat transfer unit taken along line 2-2′ of FIG. 2.

FIG. 5 is a perspective view showing a heat transfer unit of a block heater assembly according to an embodiment of the present invention.

Referring to an exploded perspective view shown in FIG. 5(a), first and second heat transfer units 410a and 410b have the same shapes in which a concave portion 415 and a convex portion 413 are formed at one side and the other side thereof. At this time, the first and second heat transfer units 410a and 410b may be sequentially disposed in the longitudinal direction of the gas line 300.

The first heat transfer unit 410a may include a concave portion 415a formed at one side thereof and a convex portion 413a formed at the other side thereof, and the second heat transfer unit 410b may include a concave portion 415b formed at one side thereof and a convex portion 413b formed at the other side thereof.

The convex portion 413 includes a coupling protrusion 4131 formed at the outer surface of the block body 411 so as to protrude a predetermined length, and the concave portion 415 includes a coupling recess 4151 formed at the outer surface of the block body 411 so as to be depressed a predetermined length and sidewalls 4153 provided at opposite ends thereof due to formation of the coupling recess 4151.

Referring to an assembled perspective view shown in FIG. 5(b), the convex portion 413a formed at the other side of the first heat transfer unit 410a and the concave portion 415b provided at one side of the second heat transfer unit 410b overlap each other and are tightly fastened to each other through fitting.

The concave portion 415b may be formed so as to have a size such that the convex portion 413a is inserted thereinto, and the width of the coupling protrusion 4131 may be equal to the width of the coupling recess 4151 such that the coupling protrusion 4131 is settled inside the coupling recess 4151. Here, the width of the coupling protrusion 4131 may be about 3 mm to 8 mm; however, the present invention is not limited thereto.

Meanwhile, heat supplied from a first heating element (not shown) may be conducted to the second heat transfer unit 410b via the concave portion 415b at one side of the second heat transfer unit 410b, which overlaps the convex portion 413a at the other side of the first heat transfer unit 410a, and heat supplied from a second heating element (not shown) may be conducted to the first heat transfer unit 410a via the convex portion 413a at the other side of the first heat transfer unit 410a, which overlaps the concave portion 415b at one side of the second heat transfer unit 410b.

As described above, a heat conduction path may be defined along arrows between the coupling protrusion 4131 at the other side of the first heat transfer unit 410a and the sidewall 4153 at one side of the second heat transfer unit 410b, which overlap each other, whereby temperature compensation may be achieved in a region B in which the first and second heat transfer units 410a and 410b are coupled to each other. Consequently, uniform distribution in temperature may be maintained over the entire first and second heat transfer units 410a and 410b. Alternatively, the block heater assembly 400 may uniformly heat the gas line 300 in the partitioned heating zones z1, z2, and z3.

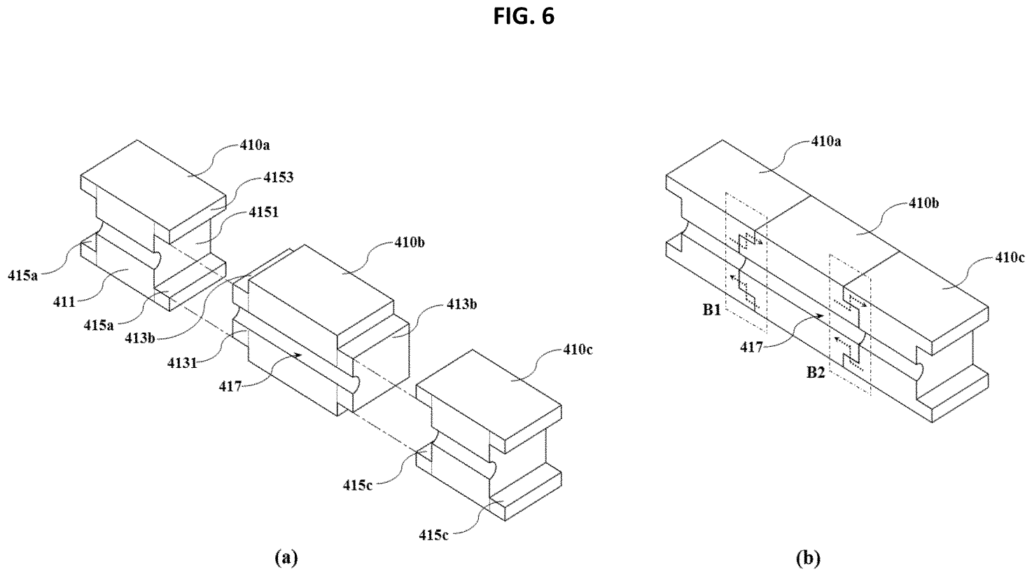

FIG. 6 is a perspective view showing a heat transfer unit of a block heater assembly according to another embodiment of the present invention

Referring to an exploded perspective view shown in FIG. 6(a), first and second heat transfer units 410a and 410b are provided at opposite sides thereof with concave portions 415a or convex portions 413b, and have different shapes. At this time, the first and second heat transfer units 410a and 410b may be alternately disposed in the longitudinal direction of the gas line 300.

Convex portions 413b may be formed at opposite sides of the second heat transfer unit 410b, and concave portions 415a and 415c may be formed at opposite sides of the first and third heat transfer units 410a and 410c, which are disposed at one side and the other side of the second heat transfer unit 410b. In the case in which the second heat transfer unit 410b is disposed between the first and third heat transfer units 410a and 410c, at the opposite sides of which the concave portions 415a and 415c are formed, respectively, as described above, it is possible for a user to easily detach the heat transfer units from each other during maintenance.

Referring to an assembled perspective view shown in FIG. 6(b), the concave portion 415a formed at the other side of the first heat transfer unit 410a and the convex portion 413b provided at one side of the second heat transfer unit 410b overlap each other and are tightly fastened to each other through fitting, and the convex portion 413b formed at the other side of the second heat transfer unit 410b and the concave portion 415c provided at one side of the third heat transfer unit 410c overlap each other and are tightly fastened to each other through fitting.

As shown, adjacent heat transfer units are formed so as to have a staggered structure in the state of overlapping each other. As a result, a heat conduction path may be formed in a coupling region B1 between the first and second heat transfer units 410a and 410b and/or a coupling region B2 between the second and third heat transfer units 410b and 410c, and temperature compensation may be achieved along the formed heat conduction path, whereby uniform distribution in temperature may be maintained over the entire first to third heat transfer units 410a, 410b, 410c. Alternatively, the block heater assembly 400 may uniformly heat the gas line 300 in the partitioned heating zones z1, z2, and z3.

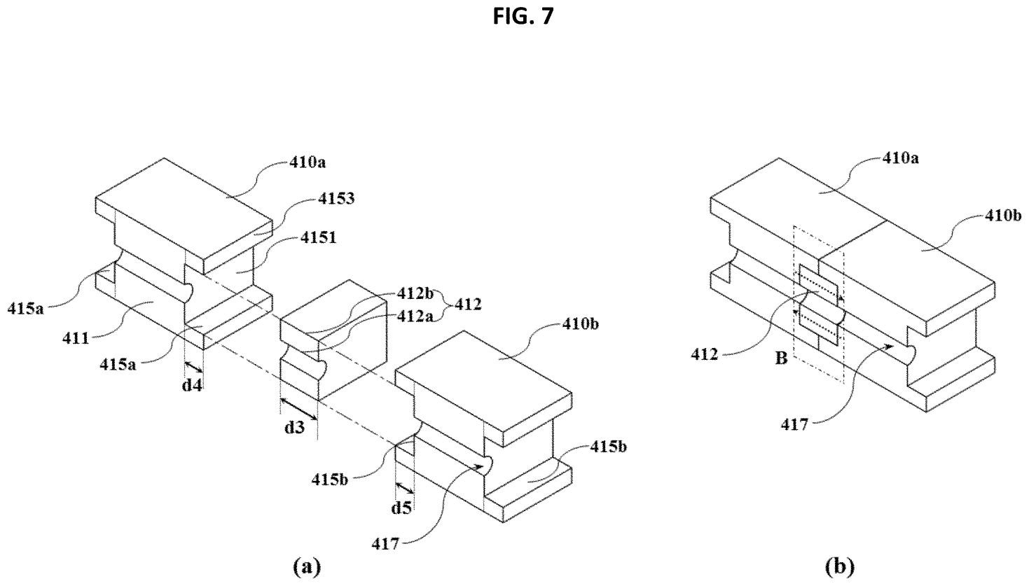

FIG. 7 is a perspective view showing a heat transfer unit of a block heater assembly according to another embodiment of the present invention.

Referring to an exploded perspective view shown in FIG. 7(a), first and second heat transfer units 410a and 410b are provided at opposite sides thereof with concave portions 415a and 415b, respectively, and have the same shapes. At this time, a connection unit 412 may be disposed between the first and second heat transfer units 410a and 410b.

The connection unit 412 may be formed so as to have a sufficient size to be inserted into the concave portions 415a and 415b of the first and second heat transfer units 410a and 410b, and the width d3 of the connection unit 412 may be equal to the sum of the first width d4 of the coupling recess 4151 at the other side of the first heat transfer unit 410a and the second width d5 of the coupling recess 4151 at one side of the second heat transfer unit 410b. Here, the width d3 of the connection unit 412 may be about 3 mm to 8 mm; however, the present invention is not limited thereto.

The connection unit 412 may be made of a material that exhibits high thermal conductivity. For example, the connection unit 412 may include any one selected from the group consisting of aluminum (Al), copper (Cu), silver (Ag), tungsten (W), and combinations thereof; however, the present invention is not limited thereto.

In addition, the connection unit 412 may be made of a material having the same thermal conductivity as the first and second heat transfer units 410a and 410b. If the thermal conductivity of the connection unit 412 is different from the thermal conductivity of the first and second heat transfer units 410a and 410b, the amount of heat that is conducted to respective regions of the gas line 300 may be different from each other, whereby uniform distribution of temperature may not be maintained over the entire gas line 300.

Referring to an assembled perspective view shown in FIG. 7(b), the connection unit 412 overlaps the concave portion 415a formed at the other side of the first heat transfer unit 410a and the concave portion 415b formed at one side of the second heat transfer unit 410b, and is tightly fastened thereto through fitting. At this time, one surface 412a of the connection unit 412 contacts the surface of the gas line 300, and one surface 4153a of the concave portion 415 contacts the other surface 412b of the connection unit 412 while being spaced apart from the gas line 300.

Meanwhile, heat supplied from a first heating element (not shown) may be conducted to the second heat transfer unit 410b via the connection unit 412, which overlaps the concave portion 415a at the other side of the first heat transfer unit 410a, and heat supplied from a second heating element (not shown) may be conducted to the first heat transfer unit 410a via the connection unit 412, which overlaps the concave portion 415b at one side of the second heat transfer unit 410b. That is, the first and second heat transfer units 410a and 410b, which are adjacent to each other, may be formed so as to have a staggered structure in the state of overlapping each other by the provision of the connection unit 412, a heat conduction path may be formed in a coupling region B1 between the first and second heat transfer units 410a and 410b, and temperature compensation may be achieved along the formed heat conduction path, whereby uniform distribution in temperature may be maintained over the entire first and second heat transfer units 410a and 410b. Alternatively, the block heater assembly 400 may uniformly heat the gas line 300 in the partitioned heating zones z1, z2, and z3.

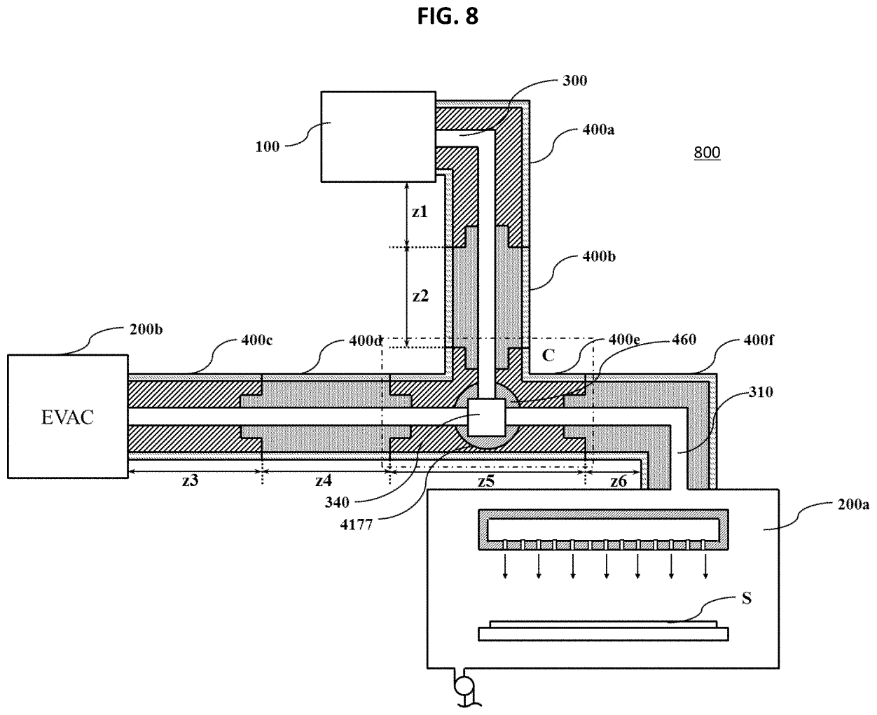

Hereinafter, the structure of a block heater applicable to a gas line 300 including a three-way valve will be described with reference to FIG. 8.

FIG. 8 is a view illustrating a block heater applied to a gas line including a three-way valve according to an embodiment of the present invention.

For convenience of description, a description overlapping that of FIG. 2 will be omitted, and a description will be given based on differences.

Referring to FIG. 8, a block heater assembly may include a plurality of block heaters 400a to 400f provided in a plurality of partitioned heating zones z1 to z6.

As shown in region C of FIG. 8, a gas line 300 provided in the fifth heating zone z5, among the heating zones z1 to z6, may further include a three-way valve configured to selectively discharge processing gas introduced from an evaporator 100 to a processing chamber 200a or to an EVAC 200b.

The three-way valve includes a valve body 340 having an inlet 341 and first and second outlets 342 and 343 formed therein and a ball (not shown) mounted in the valve body 340 to open and close a processing gas flow path or to change the direction of the processing gas flow path.

As previously described with reference to FIG. 3, the heat transfer unit 410 disposed in tight contact with the gas line 300 having the two-way valve has a shape corresponding to the shape of the gas line 300 so as to be fitted on the gas line 300. In particular, the heat transfer unit 410 is provided with a concave recess 4173 having a shape corresponding to the shape of the outer circumferential surface of the body 320 of the two-way valve so as to come into surface contact with the body 320 of the two-way valve.

However, for the heat transfer unit 410 disposed in tight contact with the gas line 300 having the three-way valve, as shown in FIG. 8, a recess 4177 formed in the body 340 of the three-way valve may have a different shape. If a predetermined recess is formed in the surface of the heat transfer unit 410 so as to have a shape corresponding to the shape of the outer circumferential surface of the valve body 340, it is impossible to mount a valve head (not shown) for a reason related to work. The reason for this is that, for the three-way valve, the position at which the valve head (not shown) is mounted is limited due to interference of the gas line, unlike the two-way valve.

Consequently, a heat transfer unit 410 of a block heater 400e according to an embodiment may be provided in the surface thereof with a predetermined recess 4177 configured to receive the three-way valve. The recess 4177 may be formed so as to have a sufficient size to receive the body 340 of the three-way valve. At this time, the inner diameter of the recess 4177 may be formed so as to be larger than the outer diameter of the valve body 340.

The block heater 400e may further include a filling portion 460 disposed in a space between the recess 4177 and the valve body 340, the filling portion 460 being made of a material exhibiting the same thermal conductivity as the heat transfer unit 410. This is provided to uniformly conduct predetermined heat from the heat transfer unit 410 to the gas line 300 and to improve heat conduction efficiency at a portion at which a contact state is released due to formation of the recess 4177. The filling portion may maximize surface contact with the gas line 300, thereby achieving effective heat transfer.

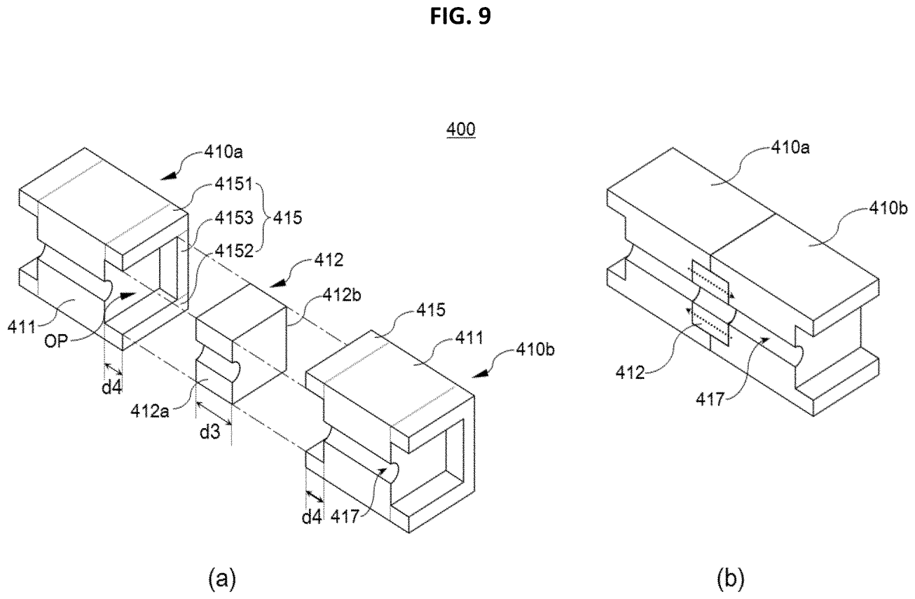

FIG. 9 is a perspective view showing a block heater assembly according to a further embodiment of the present invention.

Referring to an exploded perspective view shown in FIG. 9(a), the block heater assembly 400 may include a plurality of heat transfer units 410a and 410b and a connection unit 412 disposed between the heat transfer units 410a and 410b, and the heat transfer units 410a and 410b may be formed so as to have the same shapes.

Each of the heat transfer units 410a and 410b includes a block body 411 and a pair of protrusions 415 formed integrally at opposite side surfaces of the block body 411, and each protrusion 415 has a “[”- or “U”-shaped cross section and is formed at the outer surface of the block body 411 so as to protrude a predetermined thickness d4.

The protrusion 415 includes a first segment 4151, a second segment 4152 opposite the first segment 4151, and a third segment 4153 disposed between the first and second segments 4151 and 4152 to prevent heat supplied from a heating element (not shown) from being discharged outside, and a concave recess 417 disposed in surface contact with the gas line 300 may be opened by the protrusion 415. Each of the heat transfer units 410a and 410b may be provided at one side and the other side thereof with openings OP surrounded by the outer surface of the block body 411 and the inner circumferential surface of the protrusion 415, and the connection unit 412 may be inserted into the openings OP.

The connection unit 412 is formed so as to have a sufficient size and/or shape to be tightly inserted into the openings OP formed at the one side and the other side of the heat transfer units 410a and 410b. For example, the cross sections of the connection unit 412 and the opening OP are identical in area and shape to each other, and the width d3 of the connection unit 412 may be twice the thickness d4 of the protrusion 415 (d4=d3/2).

In addition, the connection unit 412 may be made of a material that exhibits the same thermal conductivity as the heat transfer units 410a and 410b. For example, the connection unit 412 may include any one selected from the group consisting of aluminum (Al), copper (Cu), silver (Ag), tungsten (W), and combinations thereof.

Referring to an assembled perspective view shown in FIG. 9(b), the connection unit 412 overlaps the openings OP formed at the one side and the other side of the heat transfer units 410a and 410b, and is tightly fastened thereto through fitting.

At this time, the front surface 412a of the connection unit 412 contacts the surface of the gas line 300, and the rear surface 412b of the connection unit 412, which is opposite the front surface 412a, directly contacts the third segment 4153 of the protrusion 415 constituting the heat transfer units 410a and 410b. In addition, each of the upper surface and the lower surface of the connection unit 412 directly contacts a corresponding one of the first and second segments 4151 and 4152 of the protrusion 415, and the side surface of the connection unit 412 directly contacts the block body 411.

That is, the connection unit 412 is completely surrounded by coupling between the heat transfer units 410a and 410b, and is not exposed outside. Consequently, heat supplied from the heating element (not shown) is captured in the inner circumferential surface of the protrusion 415 that directly contacts the connection unit 412, and a loss path of heat discharged outside is bypassed or extended by the third segment 4153, whereby the heat insulation efficiency of the block heater assembly 400 may be improved.

In addition, since the heat transfer units 410a and 410b overlap the connection unit 412 in a staggered structure, a heat conduction path is formed along arrows between the adjacent heat transfer units 410a and 410b, and temperature compensation may be achieved along the heat conduction path, whereby uniform distribution in temperature may be maintained. Consequently, the block heater assembly 400 may uniformly heat the gas line 300 in the partitioned heating zones z1, z2, and z3.

According to at least one embodiment of the present invention, heat having uniform temperature is provided within a predetermined section of a gas line, whereby a change in state of processing gas flowing in the gas line is inhibited, the amount of defective particles is remarkably reduced, and the quality of a deposited film is improved.

It should be noted that the effects of the present invention are not limited to the effects mentioned above, and other unmentioned effects will be clearly understood by those skilled in the art from the above description of the present invention.

Although only a few embodiments have been described above, various other embodiments may be provided. The above embodiments may be combined in various manners unless they are incompatible, and new embodiments may be realized therethrough.

It will be apparent to those skilled in the art that the present disclosure may be embodied in specific forms other than those set forth herein without departing from the spirit and essential characteristics of the present disclosure. Therefore, the above detailed description should be construed in all aspects as illustrative and not restrictive. The scope of the invention should be determined by rational interpretation of the appended claims and all changes coming within the equivalency range of the appended claims are intended to be embraced therein.

### MODE FOR INVENTION

Modes for carrying out the inventive concept have been fully described in the above-mentioned “Best mode for carrying out the invention”.

### INDUSTRIAL APPLICABILITY

The present disclosure relates to a block heater and a block heater assembly. Accordingly, the present invention has industrial applicability.

1. A block heater comprising:
a heating element configured to supply predetermined heat to a gas line; and
a heat transfer unit disposed between the gas line and the heating element to transfer heat to the gas line, wherein
the heat transfer unit comprises a convex portion or a concave portion formed on at least one side thereof in a longitudinal direction of the gas line.

2. The block heater according to claim 1, wherein the heat transfer unit is made of an aluminum (Al) material exhibiting excellent heat conduction efficiency.

3. The block heater according to claim 2, wherein an aluminum oxide (Al₂O₃) film is formed on a surface of the heat transfer unit by anodization.

4. The block heater according to claim 1, wherein the heating element is a planar heating element.

5. The block heater according to claim 1, further comprising:
a cover plate disposed opposite the heat transfer unit in a state in which the heating element is disposed therebetween, wherein
an air gap is formed between an outer surface of the cover plate and an inner surface of a housing.

6. The block heater according to claim 1, wherein the heat transfer unit comprises:
a first recess having a shape corresponding to a shape of the gas line; and
a second recess disposed adjacent to the first recess, the second recess having a shape corresponding to a shape of a connection member mounted to an end of the gas line.

7. A block heater assembly comprising:
a plurality of block heaters, each of the block heaters comprising a heat transfer unit, wherein
convex portions or concave portions are disposed at opposite ends of the heat transfer unit, and
the heat transfer units are coupled to each other through engagement between each of the convex portions and a corresponding one of the concave portions.

8. The block heater assembly according to claim 7, wherein each of the block heaters comprises at least one heating element configured to supply predetermined heat to the gas line.

9. The block heater assembly according to claim 7, wherein
one surface of each of the convex portions contacts a surface of the gas line, and
one surface of each of the concave portions contacts the other surface of a corresponding one of the convex portions while being spaced apart from the gas line.

10. The block heater assembly according to claim 7, further comprising:
a connection unit disposed between the heat transfer units, wherein
the connection unit is made of a material exhibiting identical thermal conductivity to the heat transfer units.
